(19) United States
(12) Patent Application Publication
(10) Pub. No.: US 2023/0275078 A1
(43) Pub. Date: Aug. 31, 2023

(54) TAPERED INTERCONNECT WIRES

(71) Applicant: Intel Corporation, Santa Clara, CA (US)

(72) Inventors: Harry MULJONO, San Ramon, CA (US); Horaira ABU, Fremont, CA (US)

(21) Appl. No.: 17/681,305

(22) Filed: Feb. 25, 2022

(51) Int. Cl. H01L 27/02; H01L 23/528

(52) U.S. Cl. CPC H01L 27/0207; H01L 23/528

(57) ABSTRACT

Embodiments herein relate to an interconnect that includes a first repeater, a second repeater, and a wire configured to carry an electrical signal from the first repeater to the second repeater. The wire may have a measurement adjacent to the first repeater that is greater than a measurement of the wire adjacent to the second repeater. Other embodiments may be described and claimed.

### FIELD

The present application generally relates to the field of electronic circuits and, more specifically, to tapered interconnect wires and associated apparatuses, systems, and methods.

### BACKGROUND

In chip design (such as may be used with very large-scale integration (VLSI) integrated circuits (ICs)) several data buses may carry information from one element of the chip to another. For example, in a server, there may be thousands of signals going from one processor core to another processor core in a data bus. Additionally, there may be up to 50-60 processor cores on a single die in an inter-connected mesh architecture.

In order to optimize delay and power parameters of the chip, repeaters may be employed at regular intervals along with the use of low-impedance higher-level metal wires. Additionally, some architectures may use a non-minimum wire width and spacing to reduce the impact of resistive-capacitive (RC) delay to the architecture. In addition, neighboring signals (e.g., signals along neighboring wires) in a data bus may be routed in opposite directions so that the delay impact of parasitic capacitance (i.e., the Miller effect) between the neighboring wires may be limited to only one or two repeater stages where the signal transition windows of the two wires overlap.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates an example data bus with a plurality of repeater stations, in accordance with various embodiments.

FIG. 2 illustrates an example of wires in a data bus, in accordance with various embodiments.

FIG. 3 illustrates an alternative example of wires in a data bus, in accordance with various embodiments.

FIGS. 4, 5, 6, 7, 8, and 9 illustrate alternative examples of a wire in a data bus, in accordance with various embodiments.

FIG. 10 illustrates a smart device or a computer system or a System-on-Chip (SoC) that may use, be used with, or include a tapered interconnect, in accordance with some embodiments.

### DETAILED DESCRIPTION

In the following detailed description, reference is made to the accompanying drawings that form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

As used herein, the term “wire” will be used for the metal structure along which signals are transmitted between two repeaters. The term wire may refer to the metal trace that is communicatively coupled with the respective repeaters. The metal trace may be formed of a metallic element such as, for example, aluminum, copper, and/or alloys or compounds thereof. In some embodiments, the metal trace may be coupled to, or at least partially embedded within, a dielectric material such as a printed circuit board (PCB) or some other material. Although the wires depicted herein are shown as being relatively straight, in other embodiments the wires may have some amount of curve or bend to them as may be required based on circuit design considerations.

As previously noted, VLSI chip design may include a plurality of repeater stations. Further signals along neighboring wires may be routed in opposite directions, and the wire width and spacing may be such to reduce the impact of RC delay and/or parasitic capacitance to the architecture.

Specifically, chip design may rely on the performance of various data buses on the die. In a typical server design, for example, it may be desirable for a mesh data bus to operate at a relatively high speed (e.g., between approximately 3 gigahertz (GHz) and approximately 4 GHz) and communicatively couple two processor cores or some other element of the chip. The two elements of the chip may be between approximately 3 millimeters (mm) and approximately 5 mm apart from one another.

Complimentary metal-oxide semiconductor (CMOS) repeaters may be inserted at regular intervals along the data bus, and then parameters of the wire between the repeaters may be is chosen to meet the speed requirements. In some embodiments, the selected parameter may be a width of the wire (e.g., a measurement of the wire in a direction perpendicular to a direction of propagation of an electrical signal along the wire, and parallel to a face of a PCB to which the wire is coupled) or a height of the wire (e.g., a measurement of the wire in a direction perpendicular to a direction of propagation of an electrical signal along the wire, and perpendicular to a face of a PCB to which the wire is coupled). Embodiments herein will generally be described with respect to changing the width of the wire through tapering, however it will be understood that in other embodiment the height of the wire may additionally or alternatively be similarly tapered.

Generally, the interconnect wire of the data bus may use higher-level metals of the metal stack (e.g., metal layers that are closer to the surface of a die of which they are a part). Additionally, the width and/or spacing of the wire may be sized to allow for fastest interconnect speed (e.g., on the order of 3-4 GHz, although other frequencies may be possible in other embodiments).

However, even though the metal wire between two repeater stages may be implemented with the higher metal layers, using the minimum width and minimum spacing wire, which is allowed for that layer, may not be possible due to the higher speed of the operation of the data bus. Repeaters at each stage may also be combined and co-located inside repeater station blocks. The entire bus structure may be pre-placed and pre-routed during the design process.

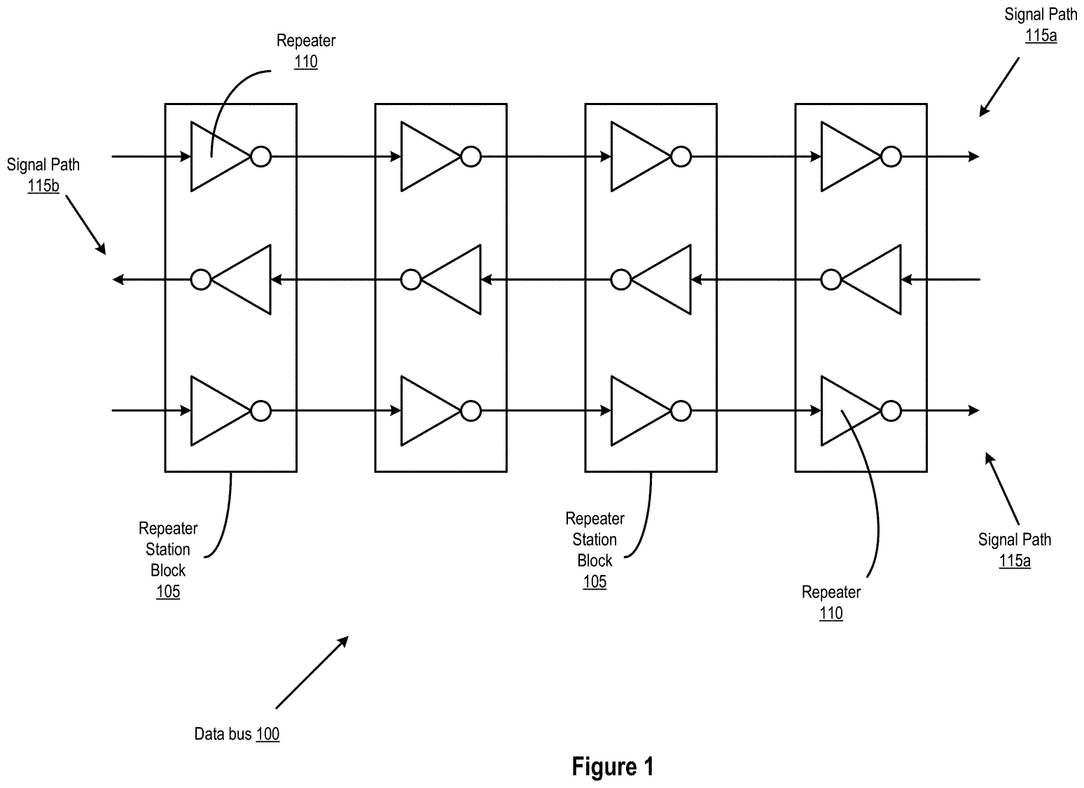

FIG. 1 illustrates an example data bus 100 with a plurality of repeater station blocks 105, in accordance with various embodiments. Specifically, the data bus may include three signal paths 115a and 115b (collectively, “signal paths 115”). As can be seen, signal path 115a provides electrical signal transfer from the left side of FIG. 1 to the right side of FIG. 1. Signal path 115b provides electrical signal transfer from the right side of FIG. 1 to the left side of FIG. 1. The electrical signals transmitted along the signal paths 115 may be control signals, power signals, or some other electrical signals that are transmitted between two elements of a chip. As previously noted, the elements may be processors, processor cores, central processing units (CPUs), or some other type of logic or processor. In other embodiments, the elements may additionally or alternatively be an element such as a sensor, an input or output, a memory, or some other element of a chip. In some embodiments, each of the signal paths 115 may be between the same two elements of the chip, while in other embodiments two or more of the signal paths 115 may be communicatively coupled with different elements of the chip than one another.

The data bus 100 may include a plurality of repeater station blocks 105, and respective ones of the repeater station blocks 105 may include one or more repeaters 110. It will be noted that FIG. 1 does not include a labelling for each and every repeater station block 105 or repeater 110 for the sake of clarity of the Figure, however it will be understood that elements of FIG. 1 may share one or more characteristics with similarly shaped labelled elements of FIG. 1.

In some legacy architectures, data buses such as data bus 100 may consume a significant amount of power and/or space on the chip due to the power requirements of the repeaters and/or the spacing requirements of the wire based on RC delay and/or parasitic capacitance requirements. As such, it may be desirable to design the wires to reduce the power and/or real estate overhead of the bus.

Embodiments herein may resolve one or more of the above-described issues by providing a tapered wire. Specifically, a measurement of the wire may change over the length of the wire between two repeater stations. By changing the measurement of the wire, power and/or delay metrics of the bus may be improved over the metrics of legacy designs.

In some embodiments, the size of the repeater (or, more specifically, the inverter of the repeater) and the width of the interconnect wire of the bus, as well as the spacing of the wires within the bus, are chosen to just meet, without significantly exceeding, speed and/or power requirements of the data bus. For example, the size of the repeater and the width/spacing of the wires may be chosen such that the design at the operating point of the chip may be met with minimal additional overhead related to process, temperature, and/or supply variation. By just meeting these requirements, the power consumption and/or area overhead of the overall bus design may be minimized.

Additionally, in embodiments herein, bidirectional connectivity between two chip elements (e.g., processors or some other element) may be achieved via a data bus with one or more repeaters positioned therebetween such as is shown in FIG. 1. The wires of the data bus may be tapered as the signal propagates from a driver gate of one repeater to a receiver gate of another repeater. The additional space created by tapering the wire may decrease wire-to-wire capacitance in the case where optimizing power consumption by the data bus is desirable. In the case where optimizing delay of the data bus is desirable, the space provided by tapering the wire may be used to increase the metal interconnect width of the wires without increasing pitch (e.g., the distance from the center of one wire to the center of another wire). As a result, embodiments herein may reduce system power consumption and/or reduce or eliminate system delay without requiring additional area overhead on the chip.

As used herein, wire tapering may refer to a design technique where an interconnect wire is divided into multiple segments, and the width of the wire segments is progressively made smaller in the direction that the electrical signal travels. Specifically, the wires may be tapered such that the portion of the wire adjacent to the driver gate of a repeater (e.g., the repeater from which the electrical signal is originating) is wider than the portion of the wire adjacent to the receiver gate of another repeater (e.g., the repeater which is receiving the electrical signal). Reduction in wire width may increase the resistance of the wire, also decrease the capacitance of the wire. The capacitance reduction may be a result of smaller wire capacitance to the top and the bottom plate of the wire due to smaller wire footprint area, as well as from increased wire-to-wire spacing between the wire and a neighboring wire. The decreased capacitance may help compensate for the increased resistance in such a way that it does not significantly increase RC delay of the data bus.

The tapering of the wire can be done using either “in place” (i.e., after fixed width wires and repeaters are pre-placed and pre-routed on the PCB) or “as construction” where tapered wired segments are placed on the PCB either through deposition, sputtering, etc.

The tapering of the wire may take a variety of different topologies. Such topologies may include a segmented taper, a linear taper, and an exponential taper (although, other tapering topologies may be present in other embodiments). As used herein, an exponential taper refers to a taper where the width of the wire varies exponentially over the length of the wire from a first width to a second width. A linear taper refers to a taper where the width of the wire changes linearly over the length of the wire from a first width to a second width. A segmented taper refers to a taper where the wire includes two or more distinct segments over along the length of the wire, and the segments have a different width than one another. It will be understood that these topologies are intended as example topologies, and other embodiments may have different topologies (e.g., a wave-like topology, a sawtooth-like topology, or a combination of topologies such as a segmented taper with linear or exponential variation in each segment).

In embodiments, a segmented tapering may be desirable for a fully-buffered data buses. Due to the relatively shorter wire lengths between repeater buffers, the difference in terms of power savings or RC delay between exponential and segmented tapering may be negligible. Additionally, segmented tapering along with neighboring wires travelling in opposite directions may ensure that the wire-to-wire spacing of the data bus remains the same across the entire wire length. Additionally, keeping the same wire width across a segment may also result in uniform metal density over the bus wire region in the layout. In some embodiments, segmented wire tapering, when done in conjunction with neighboring signals travelling in the opposite direction, may increase wire-to-wire spacing in the same wire pitch. This additional space can be used to reduce power consumption or improve delay performance of the data bus.

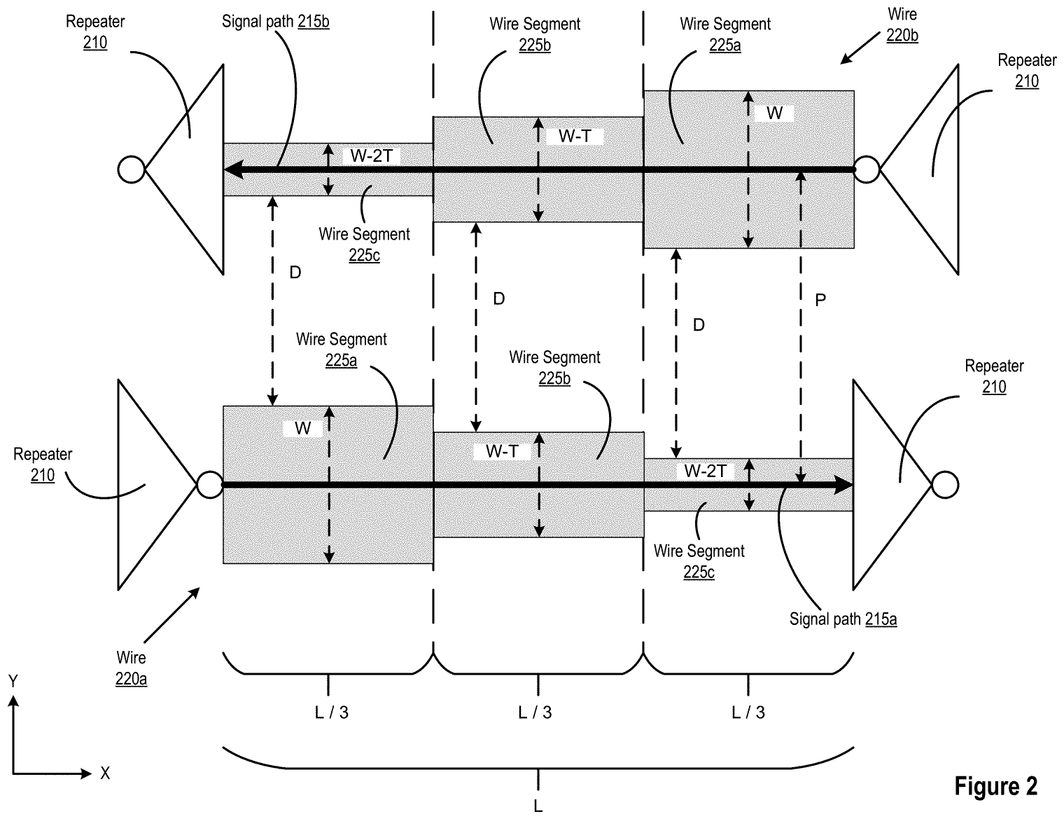

FIGS. 2-9 illustrates various examples of tapered wire topologies, in accordance with various embodiments. Specifically, FIGS. 2-9 illustrate example top-down views of the topologies such that a length of the wire between two repeaters is depicted along the X axis, and a width of the wire is depicted along the Y axis. The height of the wire, i.e. the measurement of the wire in a plan perpendicular to a face of a PCB to which the wire is coupled, is an axis Z (not shown) that extends from the plane of the Figure.

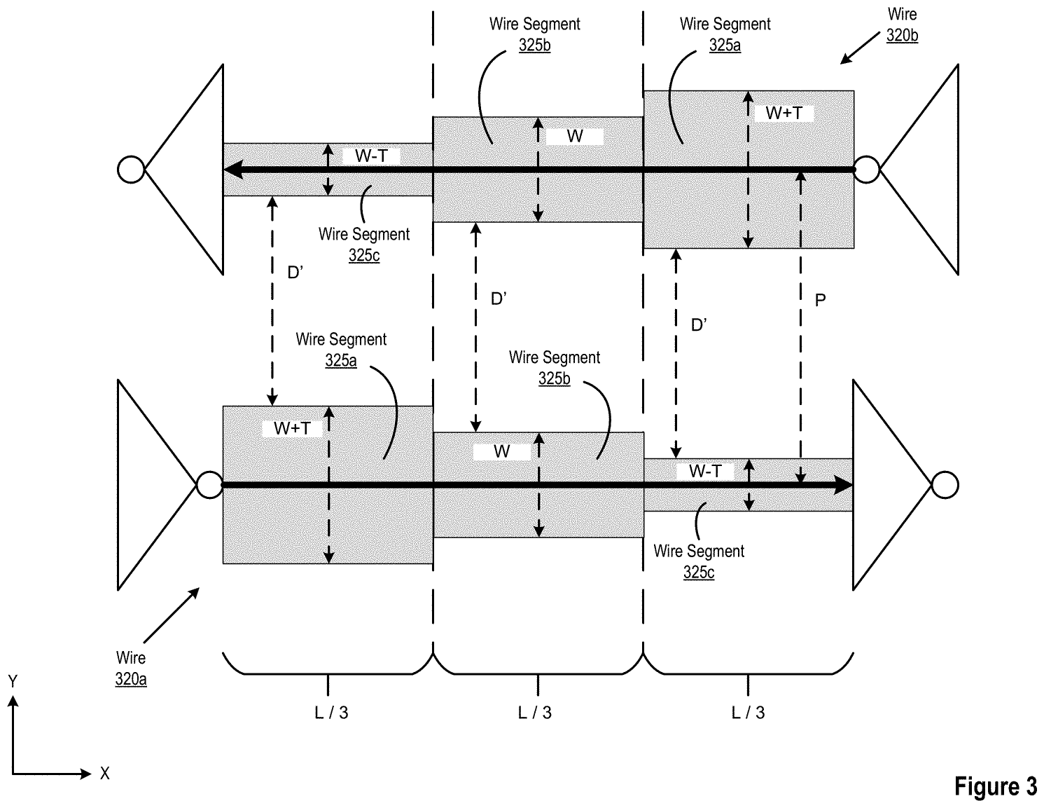

It will be understood that the topologies are illustrated for the purpose of discussion of concepts herein, and are not intended to be exhaustive. For example, other embodiments may include more or fewer segments than depicted, segments with different dimensions, etc. It will also be understood that the FIGS. 2-9 are not drawn to scale unless otherwise indicated. Additionally, elements that are initially introduced and numbered in earlier Figures (e.g., FIG. 2 or 3) may not be relabeled and re-introduced for the sake of clarity of the Figure and brevity of the associated discussion. However, it can be assumed that elements that share similar features in a later Figure may be similar to those same labeled elements in an earlier Figure unless explicitly indicated otherwise.

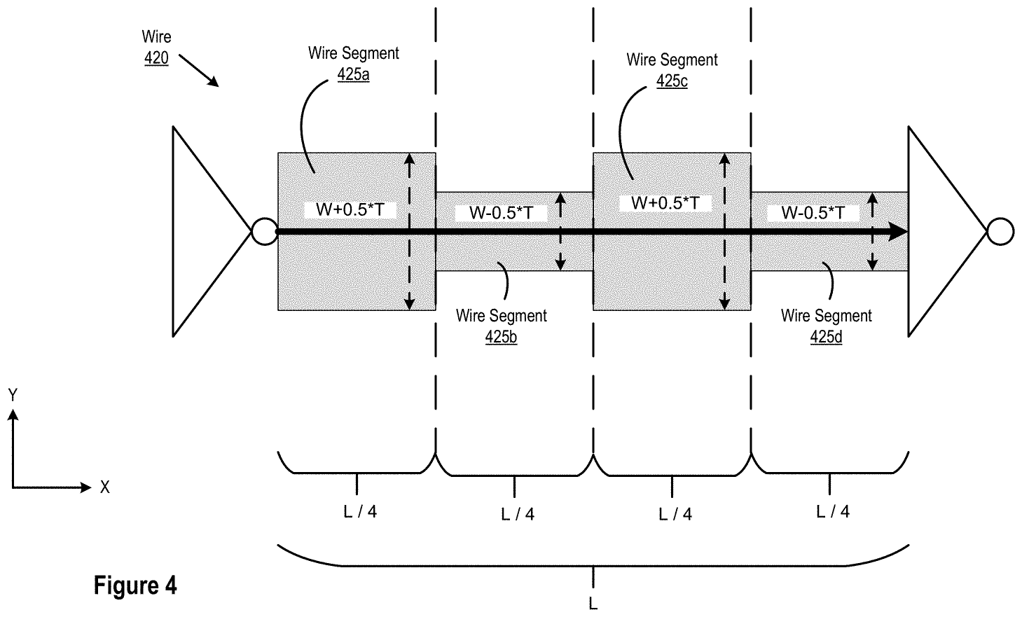

It will be further understood that even though FIGS. 4-9 each only depict a single wire, such a depiction is for the sake of lack of redundancy and embodiments herein envision at least a two-wire scenario such as is depicted in FIGS. 2 and 3. Additionally, it will be understood that although only two wires are depicted in FIGS. 2 and 3, in other embodiments the tapering concept may be expanded to include a plurality of neighboring wires arranged in a back-and-forth pattern such as that depicted in FIG. 2 or 3.

Although certain embodiments are depicted with two wires that have identical tapers, in other embodiments different wires of a data bus may be tapered differently. For example, one wire may include a segmented taper while another wire has an exponential taper, a linear taper, a taper with a different amount of segments, etc. Other variations may be present in other embodiments.

FIG. 2 illustrates an example of wires 220a and 220b (collectively, “wires 220”) in a data bus, in accordance with various embodiments. Specifically, the wires 220a and 220b may allow for an electrical signal to be transmitted along signal paths 215a and 215b between repeaters 210, which may be respectively similar to signal paths 115a and 115b, and repeaters 110 of FIG. 1. Specifically, as may be seen, wire 220a may facilitate a signal path 215a from a driver gate of a repeater 210 at the left side of FIG. 2 to a receiver gate of a repeater 210 at the right side of FIG. 2. Similarly, wire 220b may facilitate a signal path 215b from a driver gate of a repeater 210 at the right side of FIG. 2 to a receiver gate of a repeater 210 at the left side of FIG. 2.

As may be seen, the wires 220 may have a total length of L as measured along the X axis of the Figure. In some embodiments, L may be approximately 300 to 400 micrometers (“microns”) long, although in other embodiments L may be higher or lower, dependent on the type of wire used, the type of repeater used, the design requirements for the circuit, etc. As may be seen in FIG. 2, the wires 220 may each of three distinct wire segments 225a, 225b, and 225c (collectively, “wire segments 225”). Each of the wire segments 225 may have a length of L/3. In other words, if L is approximately 300 microns, each of the wire segments 225 may have a length of approximately 100 microns.

Each of the segments 225 may have a different width as shown. Specifically, segment 225a, which is adjacent to the driver gate of a repeater 210, may have a width W. In some embodiments, W may be equal to between 200 and 300 nanometers (nm), although in other embodiments W may be greater or small dependent on the type of repeater used, the type of wire used, the design requirement for the circuit, etc. Wire segment 225c, which is adjacent to the receiver gate of a repeater 210, may have a width of W−2T. Wire segment 225b, which is between segments 225a and 225c, may have a width of W−T. In some embodiments, T may be equal to between approximately 0.1*W and approximately 0.2*W. In other words, T may be between approximately 10% and 20% of W. Therefore, wire segment 225b may have a width of between 80% and 90% of W, and wire segment 225c may have a width of between 60% and 80% of W.

As may be seen in FIG. 2, the pitch P between the two wires 220 (e.g., distance between the center line of the wires 220) may remain constant over the length L of the wires 220. Additionally, because the thinner segment 225c is adjacent to the wider segment 225a in both wires 220, the distance D between the two wires is consistent over the length L of the wires 220. As may be recognized, the distance D between the two wires 220 may be greater than the distance between two non-tapered wires. For example, the distance between two non-tapered wires may be a distance D−T.

The embodiment of FIG. 2 may be desirable for a use case that is focused on power reduction. Specifically, the wires 220 may see a capacitance reduction (as compared to other non-tapered wires with a width W) that may be due to both a reduced average width of the wire and increased distance D between the wires as compared to non-tapered architectures.

The reduction in wire width W of segments 225b and 225c may increase increases the wire resistance at those segments 225b/225c as compared to a non-tapered wire. Similarly, segments 225b/225c may have decreased capacitance, which may also be proportional to the value T (as approximated to the first order). Additionally, as noted above, the spacing D between the wires 220 may be increased over non-tapered architectures. This increased resistance, decreased capacitance, and additional spacing may result in an overall delay that is comparable to, or better than, a non-tapered architecture. However, the total capacitance of each wire 220 may be reduced, which may lead to reduced power consumption of the data bus.

FIG. 3 illustrates an alternative example of wires 320a and 320b (collectively, “wires 320”) in a data bus, in accordance with various embodiments. Specifically FIG. 3, may include wires 320, which may be similar to wires 220. The wires may each have three segments, 325a, 325b, and 325c as shown. However, the width of each of the segments may be different than the width described above with respect to FIG. 2. Specifically, wire segment 325a may have a width of W+T, wire segment 325b may have a width of W, and wire segment 325c may have a width of W−T. As may be seen, the pitch P of the wires 320 may be the same as the embodiment of FIG. 2. However, the distance D′ between the two wires may be different than described above with respect to FIG. 2. Specifically, the distance D′ may be equal to D−T. However, it will be understood that in other embodiments the value P may be increased such that D′ is equal to D. Other variations may be present in other embodiments.

The embodiment of FIG. 3 may be related to improving the propagation delay of the architecture. In this case, wire-to-wire spacing D′ may be kept the same as a non-tapered architecture by widening the wire segments 325a to a width of W+T, while keeping the pitch P the same as a non-tapered architecture. In this embodiment, the tapering may not reduce the wire capacitance as compared to a non-tapered architecture, but it may reduce the overall wire impedance to be lower than that of a non-tapered architecture, thereby producing lower propagation delay.

FIG. 4 illustrates an alternative example of a wire 420 in a data bus, in accordance with various embodiments. The wire 420 may be similar to, for example, one of wires 220/320/etc. The wire may include a plurality of wire segments 425a, 425b, 425c, and 425d. As may be seen, each of the wire segments 425a/425b/425c/425d may have a length of L/4. The width of wire segments 425a and 425c may be W+0.5*T, and the width of wire segments 425b and 425d may be W−0.5*T.

Such an embodiment may be referred to as a “stubby” wire, and may be implemented in a data bus where neighboring electrical signals travel in opposite directions without increasing the pitch of the wires. This embodiment may provide improvements in one or both of delay and power reduction. For example, the delay reduction may be accomplished because segment 425a has a greater width than segment 425d, which will improve the overall speed of propagation of an electronic signal along wire 420.

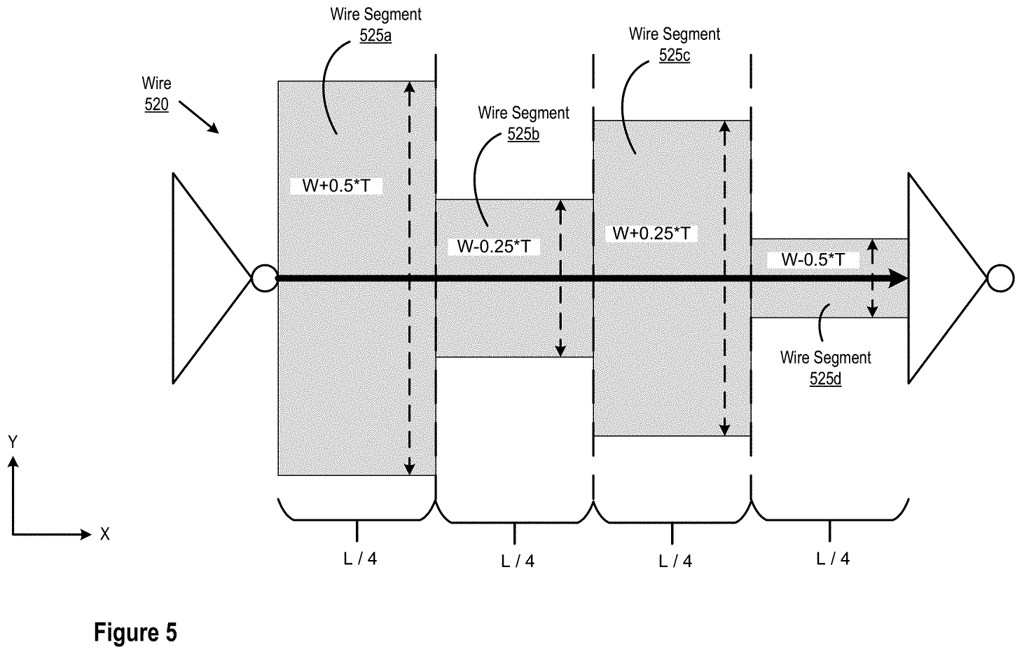

FIG. 5 illustrates an alternative example of a wire 520 in a data bus, in accordance with various embodiments. The wire 520 may be similar to, for example, one of wires 220/320/etc. The wire may include a plurality of wire segments 525a, 525b, 525c, and 525d. As may be seen, each of the wire segments 525a/525b/525c/525d may have a length of L/4. Wire segment 525a may have a width of W+0.5*T. Wire segment 525b may have a width of W−0.25*T. Wire segment 525c may have a width of W+0.25*T. Wire segment 525d may have a width of W−0.5*T. Similarly to other embodiments described herein, the pitch P and distance between neighboring wires may remain unchanged as compared to a non-tapered architecture, however this embodiment may provide additional improvements in one or both of delay and power reduction.

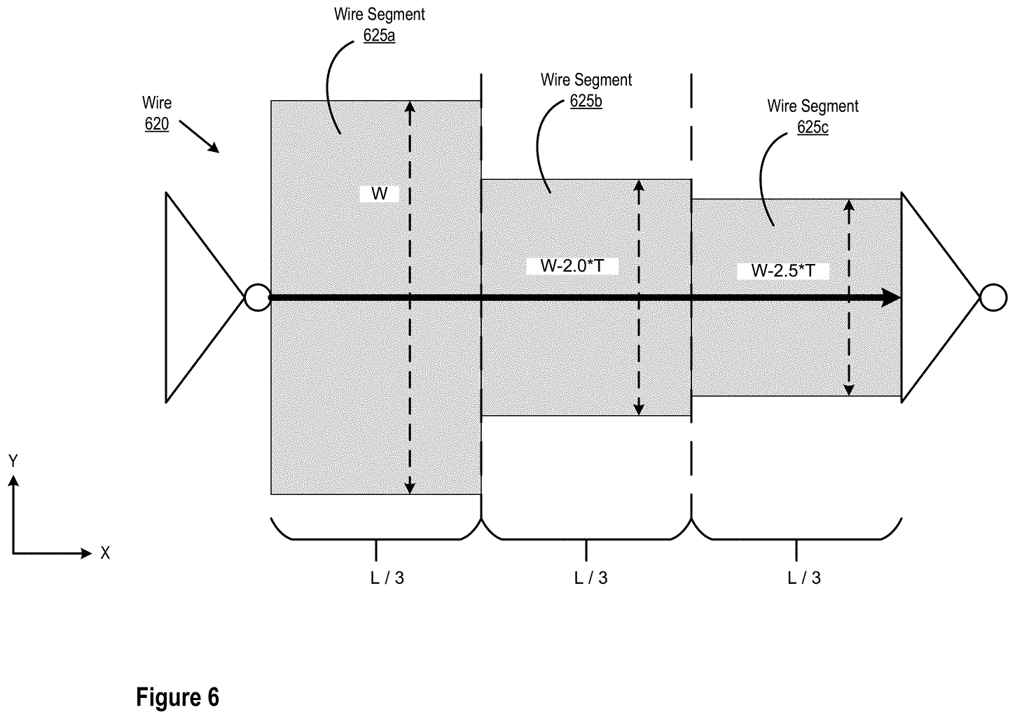

FIG. 6 illustrates an alternative example of a wire 620 in a data bus, in accordance with various embodiments. The wire 620 may be similar to, for example, one of wires 220/320/etc. The wire may include a plurality of wire segments 625a, 625b, and 625c, each with a length of L/3. It may be seen that, rather than having consistent width intervals from segment to segment, the profile of the segments 625a/625b/625c may more closely approximate an exponential tapering. Specifically, wire segment 625a may have width W. Wire segment 625b may have width W−2.0*T. Wire segment 625c may have width W−2.5*T. Such a design may assist with reducing the power consumption of the data bus as described above with respect to FIG. 2.

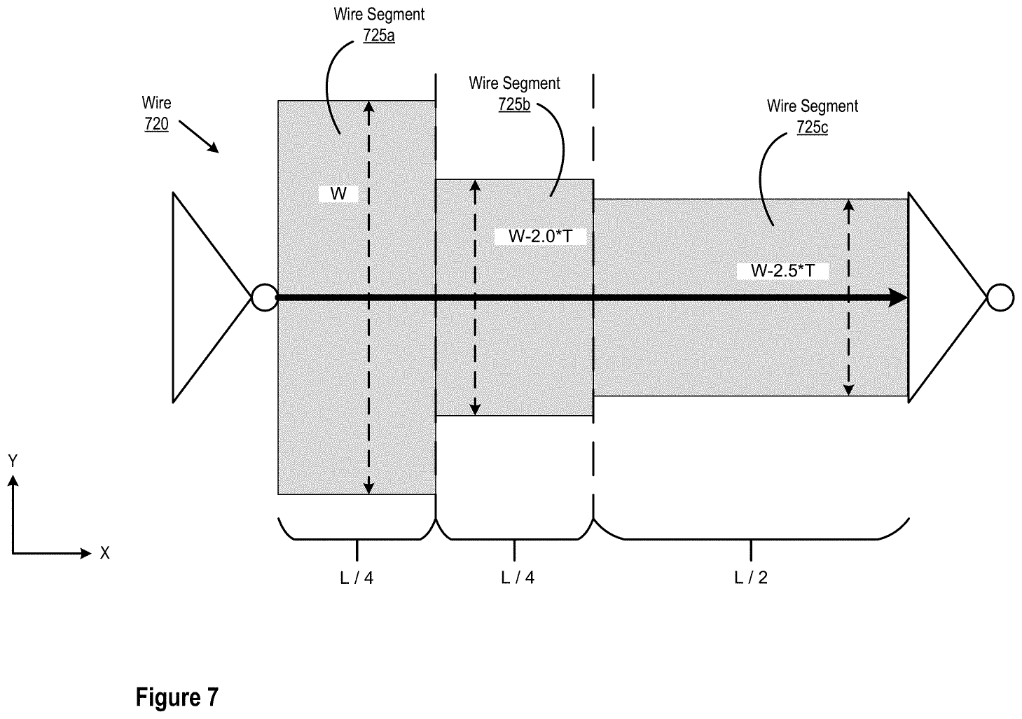

FIG. 7 illustrates an alternative example of a wire 720 in a data bus, in accordance with various embodiments. The wire 720 may be similar to, for example, one of wires 220/320/etc. The wire may include a plurality of wire segments 725a, 725b, and 725c. However, rather than each segment having a consistent length (e.g., L/3), one or more of the segments of wire 720 may have a length that is different than a length of another segment of the wire 720. Specifically, segments 725a and 725b may have a length of L/4, while segment 725c may have a length of L/2. Segments 725a, 725b, and 725c may have a width similar to that of segments 625a, 625b, and 625c, respectively. As may be seen, by varying the length of the segments 725a/725b/725c, the profile of the wire 720 may more closely approximate an exponential tapering. Similarly to FIG. 6, such a design may assist with reducing the power consumption of the data bus as described above.

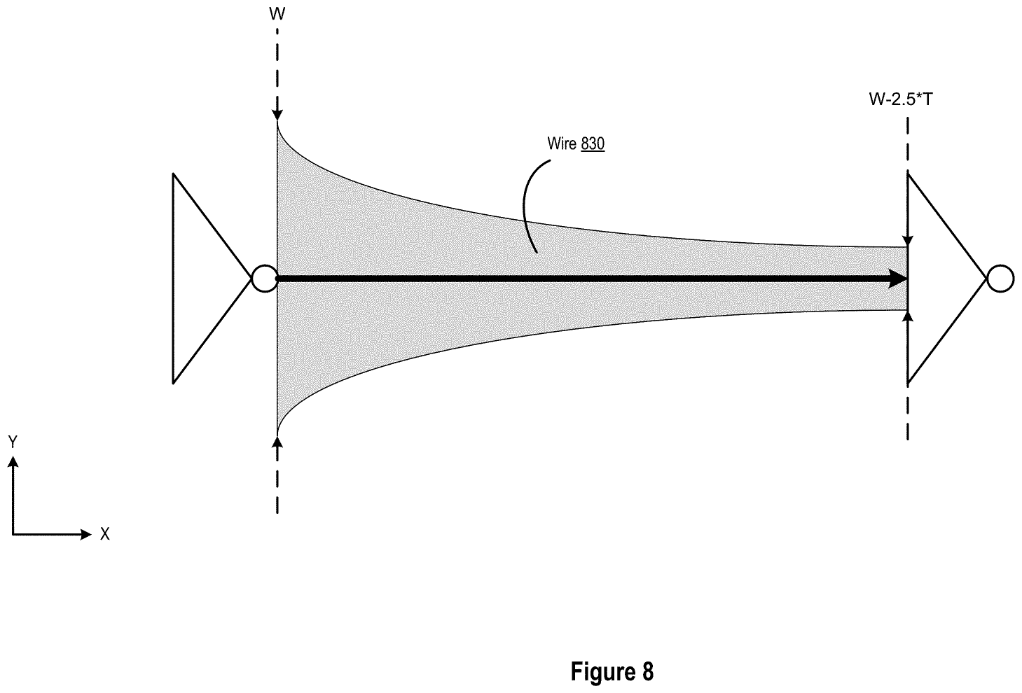

FIG. 8 illustrates an alternative example of a wire 830 in a data bus, in accordance with various embodiments. The profile of the wire 830 may be referred to as an exponential profile wherein the wire does not include discrete segments, but rather tapers in an exponential manner from a width of W to a width of W−2.5*T. Similarly to FIG. 6, such a design may assist with reducing the power consumption of the data bus as described above.

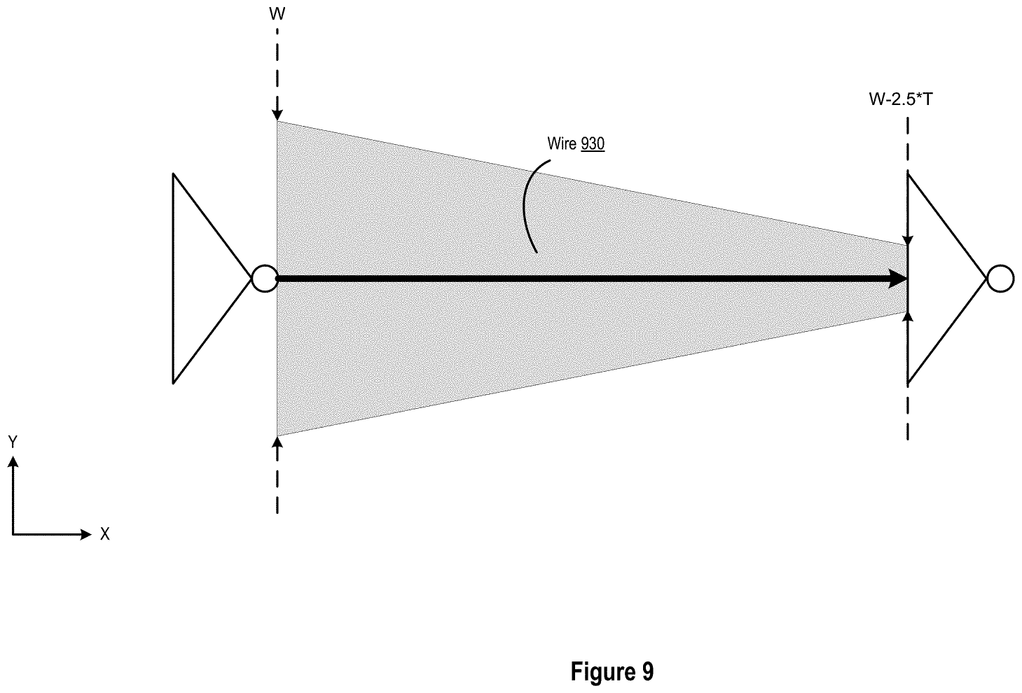

FIG. 9 illustrates an alternative example of a wire 930 in a data bus, in accordance with various embodiments. The profile of the wire 930 may be referred to as an linear profile wherein the wire does not include discrete segments, but rather tapers in a linear manner from a width of W to a width of W−2.5*T. Similarly to FIG. 6, such a design may assist with reducing the power consumption of the data bus as described above.

As has been previously noted, the various embodiments depicted herein are intended as examples of some embodiments for the sake of illustration of different concepts. Specific shapes, parameters, widths, etc. are intended for the sake of discussion, and are not intended to be exhaustive, nor are they drawn to scale. Other embodiments may include additional variations.

As may be seen in FIGS. 1-9, embodiments herein relate to a wire-tapering interconnect architecture that may provide benefits with respect to power consumption and/or delay. Some embodiments may provide an approximately 4.1% power savings, while others may provide a power savings of between 3% and 5% over non-tapered architectures. Some embodiments may provide a 1.24% delay improvement at 1 volt (V) operation, while other embodiments may provide up to a 3.54% improvement at 0.65V operation.

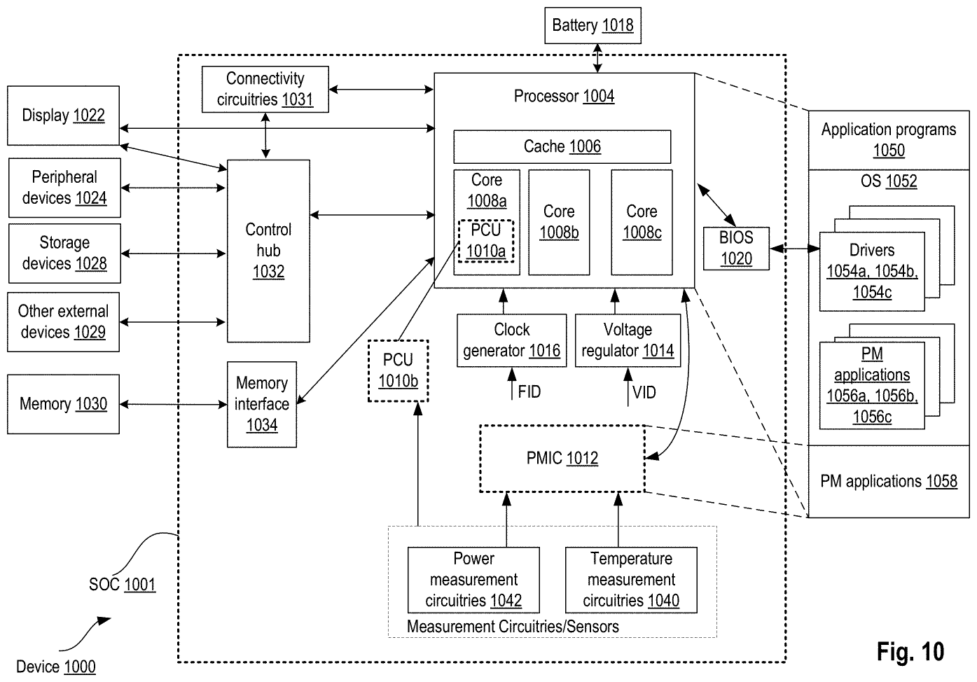

FIG. 10 illustrates a smart device or a computer system or a SoC that may use, be used with, or include a tapered interconnect, in accordance with some embodiments.

In some embodiments, device 1000 represents an appropriate computing device, such as a computing tablet, a mobile phone or smart-phone, a laptop, a desktop, an Internet-of-Things (IOT) device, a server, a wearable device, a set-top box, a wireless-enabled e-reader, or the like. It will be understood that certain components are shown generally, and not all components of such a device are shown in device 1000. The apparatus and/or software for controlling wake sources in a system to reduce power consumption in sleep state can be in the wireless connectivity circuitries 1031, PCU 1010, and/or other logic blocks (e.g., operating system 1052) that can manage power for the computer system.

In an example, the device 1000 comprises an SoC (System-on-Chip) 1001. An example boundary of the SoC 1001 is illustrated using dotted lines in FIG. 10, with some example components being illustrated to be included within SoC 1001—however, SoC 1001 may include any appropriate components of device 1000.

In some embodiments, device 1000 includes processor 1004. Processor 1004 can include one or more physical devices, such as microprocessors, application processors, microcontrollers, programmable logic devices, processing cores, or other processing means. The processing operations performed by processor 1004 include the execution of an operating platform or operating system on which applications and/or device functions are executed. The processing operations include operations related to I/O (input/output) with a human user or with other devices, operations related to power management, operations related to connecting computing device 1000 to another device, and/or the like. The processing operations may also include operations related to audio I/O and/or display I/O.

In some embodiments, processor 1004 includes multiple processing cores (also referred to as cores) 1008a, 1008b, 1008c. Although merely three cores 1008a, 1008b, 1008c are illustrated in FIG. 10, processor 1004 may include any other appropriate number of processing cores, e.g., tens, or even hundreds of processing cores. Processor cores 1008a, 1008b, 1008c may be implemented on a single integrated circuit (IC) chip. Moreover, the chip may include one or more shared and/or private caches, buses or interconnections, graphics and/or memory controllers, or other components. The cores 1008a/1008b/1008c may be coupled by a data bus such as data bus 100 that includes wires such as the wires described with respect to any of FIGS. 2-9, or some embodiment herein.

In some embodiments, processor 1004 includes cache 1006. In an example, sections of cache 1006 may be dedicated to individual cores 1008 (e.g., a first section of cache 1006 dedicated to core 1008a, a second section of cache 1006 dedicated to core 1008b, and so on). In an example, one or more sections of cache 1006 may be shared among two or more of cores 1008. Cache 1006 may be split in different levels, e.g., level 1 (L1) cache, level 2 (L2) cache, level 3 (L3) cache, etc.

In some embodiments, processor core 1004 may include a fetch unit to fetch instructions (including instructions with conditional branches) for execution by the core 1004. The instructions may be fetched from any storage devices such as the memory 1030. Processor core 1004 may also include a decode unit to decode the fetched instruction. For example, the decode unit may decode the fetched instruction into a plurality of micro-operations. Processor core 1004 may include a schedule unit to perform various operations associated with storing decoded instructions. For example, the schedule unit may hold data from the decode unit until the instructions are ready for dispatch, e.g., until all source values of a decoded instruction become available. In one embodiment, the schedule unit may schedule and/or issue (or dispatch) decoded instructions to an execution unit for execution.

The execution unit may execute the dispatched instructions after they are decoded (e.g., by the decode unit) and dispatched (e.g., by the schedule unit). In an embodiment, the execution unit may include more than one execution unit (such as an imaging computational unit, a graphics computational unit, a general-purpose computational unit, etc.). The execution unit may also perform various arithmetic operations such as addition, subtraction, multiplication, and/or division, and may include one or more an arithmetic logic units (ALUs). In an embodiment, a co-processor (not shown) may perform various arithmetic operations in conjunction with the execution unit.

Further, execution unit may execute instructions out-of-order. Hence, processor core 1004 may be an out-of-order processor core in one embodiment. Processor core 1004 may also include a retirement unit. The retirement unit may retire executed instructions after they are committed. In an embodiment, retirement of the executed instructions may result in processor state being committed from the execution of the instructions, physical registers used by the instructions being de-allocated, etc. Processor core 1004 may also include a bus unit to enable communication between components of processor core 1004 and other components via one or more buses. Processor core 1004 may also include one or more registers to store data accessed by various components of the core 1004 (such as values related to assigned app priorities and/or sub-system states (modes) association.

In some embodiments, device 1000 comprises connectivity circuitries 1031. For example, connectivity circuitries 1031 includes hardware devices (e.g., wireless and/or wired connectors and communication hardware) and/or software components (e.g., drivers, protocol stacks), e.g., to enable device 1000 to communicate with external devices. Device 1000 may be separate from the external devices, such as other computing devices, wireless access points or base stations, etc.

In an example, connectivity circuitries 1031 may include multiple different types of connectivity. To generalize, the connectivity circuitries 1031 may include cellular connectivity circuitries, wireless connectivity circuitries, etc. Cellular connectivity circuitries of connectivity circuitries 1031 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, 3rd Generation Partnership Project (3GPP) Universal Mobile Telecommunications Systems (UMTS) system or variations or derivatives, 3GPP Long-Term Evolution (LTE) system or variations or derivatives, 3GPP LTE-Advanced (LTE-A) system or variations or derivatives, Fifth Generation (5G) wireless system or variations or derivatives, 5G mobile networks system or variations or derivatives, 5G New Radio (NR) system or variations or derivatives, or other cellular service standards. Wireless connectivity circuitries (or wireless interface) of the connectivity circuitries 1031 refers to wireless connectivity that is not cellular, and can include personal area networks (such as Bluetooth, Near Field, etc.), local area networks (such as Wi-Fi), and/or wide area networks (such as WiMax), and/or other wireless communication. In an example, connectivity circuitries 1031 may include a network interface, such as a wired or wireless interface, e.g., so that a system embodiment may be incorporated into a wireless device, for example, a cell phone or personal digital assistant.

In some embodiments, device 1000 comprises control hub 1032, which represents hardware devices and/or software components related to interaction with one or more I/O devices. For example, processor 1004 may communicate with one or more of display 1022, one or more peripheral devices 1024, storage devices 1028, one or more other external devices 1029, etc., via control hub 1032. Control hub 1032 may be a chipset, a Platform Control Hub (PCH), and/or the like.

For example, control hub 1032 illustrates one or more connection points for additional devices that connect to device 1000, e.g., through which a user might interact with the system. For example, devices (e.g., devices 1029) that can be attached to device 1000 include microphone devices, speaker or stereo systems, audio devices, video systems or other display devices, keyboard or keypad devices, or other I/O devices for use with specific applications such as card readers or other devices.

As mentioned above, control hub 1032 can interact with audio devices, display 1022, etc. For example, input through a microphone or other audio device can provide input or commands for one or more applications or functions of device 1000. Additionally, audio output can be provided instead of, or in addition to display output. In another example, if display 1022 includes a touch screen, display 1022 also acts as an input device, which can be at least partially managed by control hub 1032. There can also be additional buttons or switches on computing device 1000 to provide I/O functions managed by control hub 1032. In one embodiment, control hub 1032 manages devices such as accelerometers, cameras, light sensors or other environmental sensors, or other hardware that can be included in device 1000. The input can be part of direct user interaction, as well as providing environmental input to the system to influence its operations (such as filtering for noise, adjusting displays for brightness detection, applying a flash for a camera, or other features).

In some embodiments, control hub 1032 may couple to various devices using any appropriate communication protocol, e.g., PCIe (Peripheral Component Interconnect Express), USB (Universal Serial Bus), Thunderbolt, High Definition Multimedia Interface (HDMI), Firewire, etc.

In some embodiments, display 1022 represents hardware (e.g., display devices) and software (e.g., drivers) components that provide a visual and/or tactile display for a user to interact with device 1000. Display 1022 may include a display interface, a display screen, and/or hardware device used to provide a display to a user. In some embodiments, display 1022 includes a touch screen (or touch pad) device that provides both output and input to a user. In an example, display 1022 may communicate directly with the processor 1004. Display 1022 can be one or more of an internal display device, as in a mobile electronic device or a laptop device or an external display device attached via a display interface (e.g., DisplayPort, etc.). In one embodiment display 1022 can be a head mounted display (HMD) such as a stereoscopic display device for use in virtual reality (VR) applications or augmented reality (AR) applications.

In some embodiments, and although not illustrated in the figure, in addition to (or instead of) processor 1004, device 1000 may include Graphics Processing Unit (GPU) comprising one or more graphics processing cores, which may control one or more aspects of displaying contents on display 1022.

Control hub 1032 (or platform controller hub) may include hardware interfaces and connectors, as well as software components (e.g., drivers, protocol stacks) to make peripheral connections, e.g., to peripheral devices 1024.

It will be understood that device 1000 could both be a peripheral device to other computing devices, as well as have peripheral devices connected to it. Device 1000 may have a “docking” connector to connect to other computing devices for purposes such as managing (e.g., downloading and/or uploading, changing, synchronizing) content on device 1000. Additionally, a docking connector can allow device 1000 to connect to certain peripherals that allow computing device 1000 to control content output, for example, to audiovisual or other systems.

In addition to a proprietary docking connector or other proprietary connection hardware, device 1000 can make peripheral connections via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

In some embodiments, connectivity circuitries 1031 may be coupled to control hub 1032, e.g., in addition to, or instead of, being coupled directly to the processor 1004. In some embodiments, display 1022 may be coupled to control hub 1032, e.g., in addition to, or instead of, being coupled directly to processor 1004.

In some embodiments, device 1000 comprises memory 1030 coupled to processor 1004 via memory interface 1034. Memory 1030 includes memory devices for storing information in device 1000.

In some embodiments, memory 1030 includes apparatus to maintain stable clocking as described with reference to various embodiments. Memory can include nonvolatile (state does not change if power to the memory device is interrupted) and/or volatile (state is indeterminate if power to the memory device is interrupted) memory devices. Memory device 1030 can be a dynamic random-access memory (DRAM) device, a static random-access memory (SRAM) device, flash memory device, phase-change memory device, or some other memory device having suitable performance to serve as process memory. In one embodiment, memory 1030 can operate as system memory for device 1000, to store data and instructions for use when the one or more processors 1004 executes an application or process. Memory 1030 can store application data, user data, music, photos, documents, or other data, as well as system data (whether long-term or temporary) related to the execution of the applications and functions of device 1000.

Elements of various embodiments and examples are also provided as a machine-readable medium (e.g., memory 1030) for storing the computer-executable instructions (e.g., instructions to implement any other processes discussed herein). The machine-readable medium (e.g., memory 1030) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

In some embodiments, device 1000 comprises temperature measurement circuitries 1040, e.g., for measuring temperature of various components of device 1000. In an example, temperature measurement circuitries 1040 may be embedded, or coupled or attached to various components, whose temperature are to be measured and monitored. For example, temperature measurement circuitries 1040 may measure temperature of (or within) one or more of cores 1008a, 1008b, 1008c, voltage regulator 1014, memory 1030, a mother-board of SoC 1001, and/or any appropriate component of device 1000.

In some embodiments, device 1000 comprises power measurement circuitries 1042, e.g., for measuring power consumed by one or more components of the device 1000. In an example, in addition to, or instead of, measuring power, the power measurement circuitries 1042 may measure voltage and/or current. In an example, the power measurement circuitries 1042 may be embedded, or coupled or attached to various components, whose power, voltage, and/or current consumption are to be measured and monitored. For example, power measurement circuitries 1042 may measure power, current and/or voltage supplied by one or more voltage regulators 1014, power supplied to SoC 1001, power supplied to device 1000, power consumed by processor 1004 (or any other component) of device 1000, etc.

In some embodiments, device 1000 comprises one or more voltage regulator circuitries, generally referred to as voltage regulator (VR) 1014. VR 1014 generates signals at appropriate voltage levels, which may be supplied to operate any appropriate components of the device 1000. Merely as an example, VR 1014 is illustrated to be supplying signals to processor 1004 of device 1000. In some embodiments, VR 1014 receives one or more Voltage Identification (VID) signals, and generates the voltage signal at an appropriate level, based on the VID signals. Various type of VRs may be utilized for the VR 1014. For example, VR 1014 may include a “buck” VR, “boost” VR, a combination of buck and boost VRs, low dropout (LDO) regulators, switching DC-DC regulators, constant-on-time controller-based DC-DC regulator, etc. Buck VR is generally used in power delivery applications in which an input voltage needs to be transformed to an output voltage in a ratio that is smaller than unity. Boost VR is generally used in power delivery applications in which an input voltage needs to be transformed to an output voltage in a ratio that is larger than unity. In some embodiments, each processor core has its own VR, which is controlled by PCU 1010a/b and/or PMIC 1012. In some embodiments, each core has a network of distributed LDOs to provide efficient control for power management. The LDOs can be digital, analog, or a combination of digital or analog LDOs. In some embodiments, VR 1014 includes current tracking apparatus to measure current through power supply rail(s).

In some embodiments, device 1000 comprises one or more clock generator circuitries, generally referred to as clock generator 1016. Clock generator 1016 generates clock signals at appropriate frequency levels, which may be supplied to any appropriate components of device 1000. Merely as an example, clock generator 1016 is illustrated to be supplying clock signals to processor 1004 of device 1000. In some embodiments, clock generator 1016 receives one or more Frequency Identification (FID) signals, and generates the clock signals at an appropriate frequency, based on the FID signals.

In some embodiments, device 1000 comprises battery 1018 supplying power to various components of device 1000. Merely as an example, battery 1018 is illustrated to be supplying power to processor 1004. Although not illustrated in the figures, device 1000 may comprise a charging circuitry, e.g., to recharge the battery, based on Alternating Current (AC) power supply received from an AC adapter.

In some embodiments, device 1000 comprises Power Control Unit (PCU) 1010 (also referred to as Power Management Unit (PMU), Power Controller, etc.). In an example, some sections of PCU 1010 may be implemented by one or more processing cores 1008, and these sections of PCU 1010 are symbolically illustrated using a dotted box and labelled PCU 1010a. In an example, some other sections of PCU 1010 may be implemented outside the processing cores 1008, and these sections of PCU 1010 are symbolically illustrated using a dotted box and labelled as PCU 1010b. PCU 1010 may implement various power management operations for device 1000. PCU 1010 may include hardware interfaces, hardware circuitries, connectors, registers, etc., as well as software components (e.g., drivers, protocol stacks), to implement various power management operations for device 1000.

In some embodiments, device 1000 comprises Power Management Integrated Circuit (PMIC) 1012, e.g., to implement various power management operations for device 1000. In some embodiments, PMIC 1012 is a Reconfigurable Power Management ICs (RPMICs) and/or an IMVP (Intel® Mobile Voltage Positioning). In an example, the PMIC is within an IC chip separate from processor 1004. The may implement various power management operations for device 1000. PMIC 1012 may include hardware interfaces, hardware circuitries, connectors, registers, etc., as well as software components (e.g., drivers, protocol stacks), to implement various power management operations for device 1000.

In an example, device 1000 comprises one or both PCU 1010 or PMIC 1012. In an example, any one of PCU 1010 or PMIC 1012 may be absent in device 1000, and hence, these components are illustrated using dotted lines.

Various power management operations of device 1000 may be performed by PCU 1010, by PMIC 1012, or by a combination of PCU 1010 and PMIC 1012. For example, PCU 1010 and/or PMIC 1012 may select a power state (e.g., P-state) for various components of device 1000. For example, PCU 1010 and/or PMIC 1012 may select a power state (e.g., in accordance with the ACPI (Advanced Configuration and Power Interface) specification) for various components of device 1000. Merely as an example, PCU 1010 and/or PMIC 1012 may cause various components of the device 1000 to transition to a sleep state, to an active state, to an appropriate C state (e.g., CO state, or another appropriate C state, in accordance with the ACPI specification), etc. In an example, PCU 1010 and/or PMIC 1012 may control a voltage output by VR 1014 and/or a frequency of a clock signal output by the clock generator, e.g., by outputting the VID signal and/or the FID signal, respectively. In an example, PCU 1010 and/or PMIC 1012 may control battery power usage, charging of battery 1018, and features related to power saving operation.

The clock generator 1016 can comprise a phase locked loop (PLL), frequency locked loop (FLL), or any suitable clock source. In some embodiments, each core of processor 1004 has its own clock source. As such, each core can operate at a frequency independent of the frequency of operation of the other core. In some embodiments, PCU 1010 and/or PMIC 1012 performs adaptive or dynamic frequency scaling or adjustment. For example, clock frequency of a processor core can be increased if the core is not operating at its maximum power consumption threshold or limit. In some embodiments, PCU 1010 and/or PMIC 1012 determines the operating condition of each core of a processor, and opportunistically adjusts frequency and/or power supply voltage of that core without the core clocking source (e.g., PLL of that core) losing lock when the PCU 1010 and/or PMIC 1012 determines that the core is operating below a target performance level. For example, if a core is drawing current from a power supply rail less than a total current allocated for that core or processor 1004, then PCU 1010 and/or PMIC 1012 can temporality increase the power draw for that core or processor 1004 (e.g., by increasing clock frequency and/or power supply voltage level) so that the core or processor 1004 can perform at higher performance level. As such, voltage and/or frequency can be increased temporality for processor 1004 without violating product reliability.

In an example, PCU 1010 and/or PMIC 1012 may perform power management operations, e.g., based at least in part on receiving measurements from power measurement circuitries 1042, temperature measurement circuitries 1040, charge level of battery 1018, and/or any other appropriate information that may be used for power management. To that end, PMIC 1012 is communicatively coupled to one or more sensors to sense/detect various values/variations in one or more factors having an effect on power/thermal behavior of the system/platform. Examples of the one or more factors include electrical current, voltage droop, temperature, operating frequency, operating voltage, power consumption, inter-core communication activity, etc. One or more of these sensors may be provided in physical proximity (and/or thermal contact/coupling) with one or more components or logic/IP blocks of a computing system. Additionally, sensor(s) may be directly coupled to PCU 1010 and/or PMIC 1012 in at least one embodiment to allow PCU 1010 and/or PMIC 1012 to manage processor core energy at least in part based on value(s) detected by one or more of the sensors.

Also illustrated is an example software stack of device 1000 (although not all elements of the software stack are illustrated). Merely as an example, processors 1004 may execute application programs 1050, Operating System 1052, one or more Power Management (PM) specific application programs (e.g., generically referred to as PM applications 1058), and/or the like. PM applications 1058 may also be executed by the PCU 1010 and/or PMIC 1012. OS 1052 may also include one or more PM applications 1056a, 1056b, 1056c. The OS 1052 may also include various drivers 1054a, 1054b, 1054c, etc., some of which may be specific for power management purposes. In some embodiments, device 1000 may further comprise a Basic Input/output System (BIOS) 1020. BIOS 1020 may communicate with OS 1052 (e.g., via one or more drivers 1054), communicate with processors 1004, etc.

For example, one or more of PM applications 1058, 1056, drivers 1054, BIOS 1020, etc. may be used to implement power management specific tasks, e.g., to control voltage and/or frequency of various components of device 1000, to control wake-up state, sleep state, and/or any other appropriate power state of various components of device 1000, control battery power usage, charging of the battery 1018, features related to power saving operation, etc.

In some embodiments, battery 1018 is a Li-metal battery with a pressure chamber to allow uniform pressure on a battery. The pressure chamber is supported by metal plates (such as pressure equalization plate) used to give uniform pressure to the battery. The pressure chamber may include pressured gas, elastic material, spring plate, etc. The outer skin of the pressure chamber is free to bow, restrained at its edges by (metal) skin, but still exerts a uniform pressure on the plate that is compressing the battery cell. The pressure chamber gives uniform pressure to battery, which is used to enable high-energy density battery with, for example, 20% more battery life.

In some embodiments, pCode executing on PCU 1010a/b has a capability to enable extra compute and telemetries resources for the runtime support of the pCode. Here pCode refers to a firmware executed by PCU 1010a/b to manage performance of the SoC 1001. For example, pCode may set frequencies and appropriate voltages for the processor. Part of the pCode are accessible via OS 1052. In various embodiments, mechanisms and methods are provided that dynamically change an Energy Performance Preference (EPP) value based on workloads, user behavior, and/or system conditions. There may be a well-defined interface between OS 1052 and the pCode. The interface may allow or facilitate the software configuration of several parameters and/or may provide hints to the pCode. As an example, an EPP parameter may inform a pCode algorithm as to whether performance or battery life is more important.

This support may be done as well by the OS 1052 by including machine-learning support as part of OS 1052 and either tuning the EPP value that the OS hints to the hardware (e.g., various components of SoC 1001) by machine-learning prediction, or by delivering the machine-learning prediction to the pCode in a manner similar to that done by a Dynamic Tuning Technology (DTT) driver. In this model, OS 1052 may have visibility to the same set of telemetries as are available to a DTT. As a result of a DTT machine-learning hint setting, pCode may tune its internal algorithms to achieve optimal power and performance results following the machine-learning prediction of activation type. The pCode as example may increase the responsibility for the processor utilization change to enable fast response for user activity, or may increase the bias for energy saving either by reducing the responsibility for the processor utilization or by saving more power and increasing the performance lost by tuning the energy saving optimization. This approach may facilitate saving more battery life in case the types of activities enabled lose some performance level over what the system can enable. The pCode may include an algorithm for dynamic EPP that may take the two inputs, one from OS 1052 and the other from software such as DTT, and may selectively choose to provide higher performance and/or responsiveness. As part of this method, the pCode may enable in the DTT an option to tune its reaction for the DTT for different types of activity.

Some non-limiting Examples of various embodiments are presented below.

Example 1 includes an apparatus for use in an electrical device, wherein the apparatus comprises: a first repeater; a second repeater; and a wire coupled with the first repeater and the second repeater, wherein the wire is to carry an electrical signal along a signal path from the first repeater to the second repeater, wherein the wire has a first segment adjacent to the first repeater and a second segment adjacent to the second repeater; wherein: the first segment has a first measurement perpendicular to a length of the wire; the second segment has a second measurement perpendicular to the length of the wire; and the first measurement is greater than the second measurement.

Example 2 includes the apparatus of example 1, and/or some other example herein, wherein the first measurement and the second measurement are a width of the wire.

Example 3 includes the apparatus of example 2, and/or some other example herein, wherein the wire has an average width of less than or equal to 300 nanometers (nm).

Example 4 includes the apparatus of any of examples 1-3, and/or some other example herein, wherein the first measurement and the second measurement are a height of the wire.

Example 5 includes the apparatus of any of examples 1-4, and/or some other example herein, wherein the length of the wire is measured in a direction parallel to a direction of propagation of the electrical signal.

Example 6 includes the apparatus of example 5, and/or some other example herein, wherein the length of the wire is between 300 and 400 micrometers (microns) long.

Example 7 includes the apparatus of any of examples 1-6, and/or some other example herein, wherein the first measurement is between 10% and 20% greater than the second measurement.

Example 8 includes the apparatus of any of examples 1-6, and/or some other example herein, wherein the first measurement is 40% greater than the second measurement.

Example 9 includes the apparatus of any of examples 1-8, and/or some other example herein, wherein a profile of the wire between the first measurement and the second measurement changes linearly from the first repeater to the second repeater.

Example 10 includes the apparatus of any of examples 1-8, and/or some other example herein, wherein a profile of the wire between the first measurement and the second measurement changes exponentially from the first repeater to the second repeater.

Example 11 includes the apparatus of any of examples 1-10, and/or some other example herein, wherein: the first segment has the first measurement over a length of the first segment; and the second segment has the second measurement over a length of the second segment.

Example 12 includes the apparatus of any of examples 1-11, and/or some other example herein, wherein a length of the first segment is substantially the same as a length of the second segment.

Example 13 includes the apparatus of any of examples 1-11, and/or some other example herein, wherein a length of the first segment is different from a length of the second segment.

Example 14 includes the apparatus of any of examples 1-13, and/or some other example herein, wherein the wire further includes a third segment between the first segment and the second segment, wherein the third segment has a third measurement that is parallel to the first measurement, and the third measurement is different than the first measurement and the second measurement.

Example 15 includes the apparatus of any of examples 1-14, and/or some other example herein, wherein the wire is a first wire, and further comprising a second wire that is parallel to the first wire, and wherein: the second wire is to carry a second electrical signal from the second repeater to the first repeater; the second wire has a third segment adjacent to the second repeater and a fourth segment adjacent to the first repeater; the third segment has a third measurement that is parallel to the first measurement; the fourth segment has a fourth measurement that is parallel to the first measurement; and the third measurement is greater than the fourth measurement.

Example 16 includes the apparatus of example 15, and/or some other example herein, wherein a pitch of the first wire and the second wire adjacent to the first repeater is substantially the same as a pitch of the first wire and the second wire adjacent to the second repeater.

Example 17 includes the apparatus of example 15, and/or some other example herein, wherein the first segment is adjacent to the fourth segment and the second segment is adjacent to the third segment; and a distance between the first segment and the fourth segment is substantially the same as a distance between the second segment and the third segment.

Example 18 includes an apparatus for use in an electronic device, wherein the apparatus comprises: a first repeater stage; a second repeater stage; a first wire configured to convey an electrical signal along a length of the first wire from the first repeater stage to the second repeater stage, wherein the first wire has a first width as measured in a direction perpendicular to the length of the first wire that is greater at a first segment of the first wire adjacent to the first repeater stage than a second width at a second segment of the first wire adjacent to the second repeater stage; and a second wire configured to convey an electrical signal along a length of the second wire from the second repeater stage to the first repeater stage, wherein the second wire has a third width as measured in a direction perpendicular to the length of the second wire that is greater at a first segment of the second wire adjacent to the second repeater stage than a fourth width at a second segment of the second wire adjacent to the first repeater stage.

Example 19 includes the apparatus of example 18, and/or some other example herein, wherein the first wire has an average width of less than or equal to 300 nanometers (nm).

Example 20 includes the apparatus of any of examples 18-19, and/or some other example herein, wherein the length of the first wire is measured in a direction parallel to a direction of propagation of the electrical signal.

Example 21 includes the apparatus of example 20, and/or some other example herein, wherein the length of the first wire is between 300 and 400 micrometers (microns) long.

Example 22 includes the apparatus of any of examples 18-21, and/or some other example herein, wherein the first width is between 10% and 20% greater than the second width.

Example 23 includes the apparatus of any of examples 18-21, and/or some other example herein, wherein the first width is 40% greater than the second width.

Example 24 includes the apparatus of any of examples 18-23, and/or some other example herein, wherein a width of the first wire changes linearly from the first width to the second width.

Example 25 includes the apparatus of any of examples 18-23, and/or some other example herein, wherein a width of the first wire changes exponentially from the first width to the second width.

Example 26 includes the apparatus of any of examples 18-25, and/or some other example herein, wherein: the first segment has the first width over a length of the first segment; and the second segment has the second width over a length of the second segment.

Example 27 includes the apparatus of any of examples 18-26, and/or some other example herein, wherein the first width is substantially the same as the third width.

Example 28 includes the apparatus of any of examples 18-26, and/or some other example herein, wherein the first width is different than the third width.

Example 29 includes the apparatus of any of examples 18-28, and/or some other example herein, wherein a length of the first segment is substantially the same as a length of the second segment.

Example 30 includes the apparatus of any of examples 18-28, wherein a length of the first segment is different from a length of the second segment.

Example 31 includes the apparatus of any of examples 18-30, wherein the first wire further includes a third segment between the first segment of the first wire and the second segment of the first wire, wherein the third segment has a fifth width that is different from the first width and the second width.

Example 32 includes the apparatus of any of examples 18-31, wherein a pitch of the first segment of the first wire and the second segment of the second wire is substantially the same as a pitch of the second segment of the first wire and the first segment of the second wire.

Example 33 includes the apparatus of any of examples 18-32, wherein a distance between the first segment of the first wire and the second segment of the second wire is substantially the same as a distance between the second segment of the first wire and the first segment of the second wire.

Example 34 includes an electronic device comprising: a plurality of repeater stages, wherein a respective repeater stage of the plurality of repeater stages includes at least two repeaters; a first wire configured to convey an electrical signal from a first repeater of a first repeater stage to a second repeater of a second repeater stage; and a second wire configured to convey an electrical signal from a third repeater of the second repeater stage to a fourth repeater of the first repeater stage; wherein a first width of the first wire adjacent to the first repeater is greater than a second width of the first wire adjacent to the second repeater; and wherein a third width of the second wire adjacent to the third repeater is greater than a fourth width of the second wire adjacent to the fourth repeater.

Example 35 includes the electronic device of example 34, and/or some other example herein, wherein the first wire has an average width of less than or equal to 300 nanometers (nm).

Example 36 includes the electronic device of any of examples 34-35, and/or some other example herein, wherein the length of the first wire is measured in a direction parallel to a direction of propagation of the electrical signal.

Example 37 includes the electronic device of example 36, and/or some other example herein, wherein the length of the first wire is between 300 and 400 micrometers (microns) long.

Example 38 includes the electronic device of any of examples 34-37, and/or some other example herein, wherein the first width is between 10% and 20% greater than the second width.

Example 39 includes the electronic device of any of examples 34-37, and/or some other example herein, wherein the first width is 40% greater than the second width.

Example 40 includes the electronic device of any of examples 34-39, and/or some other example herein, wherein a width of the first wire changes linearly from the first width to the second width.

Example 41 includes the electronic device of any of examples 34-39, and/or some other example herein, wherein a width of the first wire changes exponentially from the first width to the second width.

Example 42 includes the electronic device of any of examples 34-41, and/or some other example herein, wherein the first width is substantially the same as the third width.

Example 43 includes the electronic device of any of examples 34-41, and/or some other example herein, wherein the first width is different than the third width.

Example 42 includes the electronic device of any of examples 34-43, and/or some other example herein, wherein: the first wire has a first segment adjacent to the first repeater and a second segment adjacent to the second repeater; the first segment has the first width over a length of the first segment; and the second segment has the second width over a length of the second segment.

Example 43 includes the electronic device of any of examples 34-42, and/or some other example herein, wherein a length of the first segment is substantially the same as a length of the second segment.

Example 44 includes the electronic device of any of examples 34-42, and/or some other example herein, wherein a length of the first segment is different from a length of the second segment.

Example 45 includes the electronic device of any of examples 42-44, and/or some other example herein, wherein the first wire further includes a third segment between the first segment of the first wire and the second segment of the first wire, wherein the third segment has a fifth width that is different from the first width and the second width.

Example 46 includes the electronic device of any of examples 34-45, and/or some other example herein, wherein a pitch of the first wire and the second wire adjacent the first repeater stage is substantially the same as the pitch of the first wire and the second wire adjacent the second repeater stage.

Example 47 includes the electronic device of any of examples 34-46, and/or some other example herein, wherein a distance between the first wire and the second wire adjacent to the first repeater stage is substantially the same as the distance between the first wire and the second wire adjacent to the second repeater stage.

Example 48 includes the electronic device of any of examples 34-47, and/or some other example herein, wherein the first repeater stage and the second repeater stage are adjacent repeater stages in the plurality of repeater stages.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1. An apparatus for use in an electrical device, wherein the apparatus comprises:
a first repeater;
a second repeater; and
a wire coupled with the first repeater and the second repeater, wherein the wire is to carry an electrical signal along a signal path from the first repeater to the second repeater, wherein the wire has a first segment adjacent to the first repeater and a second segment adjacent to the second repeater;
wherein:
the first segment has a first measurement perpendicular to a length of the wire;
the second segment has a second measurement perpendicular to the length of the wire; and
the first measurement is greater than the second measurement.

2. The apparatus of claim 1, wherein the first measurement and the second measurement are a width of the wire.

3. The apparatus of claim 2, wherein the wire has an average width of less than or equal to 300 nanometers (nm).

4. The apparatus of claim 1, wherein the first measurement and the second measurement are a height of the wire.

5. The apparatus of claim 1, wherein the length of the wire is measured in a direction parallel to a direction of propagation of the electrical signal.

6. The apparatus of claim 5, wherein the length of the wire is between 300 and 400 micrometers (microns) long.

7. The apparatus of claim 1, wherein the first measurement is between 10% and 20% greater than the second measurement.

8. The apparatus of claim 1, wherein the first measurement is 40% greater than the second measurement.

9. An apparatus for use in an electronic device, wherein the apparatus comprises:
a first repeater stage;
a second repeater stage;
a first wire configured to convey an electrical signal along a length of the first wire from the first repeater stage to the second repeater stage, wherein the first wire has a first width as measured in a direction perpendicular to the length of the first wire that is greater at a first segment of the first wire adjacent to the first repeater stage than a second width at a second segment of the first wire adjacent to the second repeater stage; and
a second wire configured to convey an electrical signal along a length of the second wire from the second repeater stage to the first repeater stage, wherein the second wire has a third width as measured in a direction perpendicular to the length of the second wire that is greater at a first segment of the second wire adjacent to the second repeater stage than a fourth width at a second segment of the second wire adjacent to the first repeater stage.

10. The apparatus of claim 9, wherein:
the first segment has the first width over a length of the first segment; and
the second segment has the second width over a length of the second segment.

11. The apparatus of claim 9, wherein a length of the first segment is substantially the same as a length of the second segment.

12. The apparatus of claim 9, wherein a length of the first segment is different from a length of the second segment.

13. The apparatus of claim 9, wherein a pitch of the first segment of the first wire and the second segment of the second wire is substantially the same as a pitch of the second segment of the first wire and the first segment of the second wire.

14. The apparatus of claim 9, wherein a distance between the first segment of the first wire and the second segment of the second wire is substantially the same as a distance between the second segment of the first wire and the first segment of the second wire.

15. An electronic device comprising:
a plurality of repeater stages, wherein a respective repeater stage of the plurality of repeater stages includes at least two repeaters;
a first wire configured to convey an electrical signal from a first repeater of a first repeater stage to a second repeater of a second repeater stage; and
a second wire configured to convey an electrical signal from a third repeater of the second repeater stage to a fourth repeater of the first repeater stage;
wherein a first width of the first wire adjacent to the first repeater is greater than a second width of the first wire adjacent to the second repeater; and
wherein a third width of the second wire adjacent to the third repeater is greater than a fourth width of the second wire adjacent to the fourth repeater.

16. The electronic device of claim 15, wherein a width of the first wire changes linearly from the first width to the second width.

17. The electronic device of claim 15, wherein a width of the first wire changes exponentially from the first width to the second width.

18. The electronic device of claim 15, wherein the first width is substantially the same as the third width.

19. The electronic device of claim 15, wherein the first width is different than the third width.

20. The electronic device of claim 15, wherein the first repeater stage and the second repeater stage are adjacent repeater stages in the plurality of repeater stages.
